(19) United States
(12) Patent Application Publication
(10) Pub. No.: US 2015/0235931 A1
(43) Pub. Date: Aug. 20, 2015

(54) SEMICONDUCTOR DEVICE

(71) Applicant: ROHM CO., LTD., Kyoto-shi (JP)

(72) Inventors: Gen MUTO, Kyoto-shi (JP); Hideki SAWADA, Kyoto-shi (JP); Tomoki TAKESHITA, Kyoto-shi (JP)

(21) Appl. No.: 14/626,166

(22) Filed: Feb. 19, 2015

(30) Foreign Application Priority Data
Feb. 20, 2014 (JP) 2014-030395

(51) Int. Cl. H01L 23/495; H05K 1/03; H05K 1/11; H05K 1/18

(52) U.S. Cl. CPC H01L 23/49575; H05K 1/181; H05K 1/0306; H05K 1/115; H05K 2201/10015; H05K 2201/10507

(57) ABSTRACT

A semiconductor device includes a semiconductor chip, a plurality of passive electronic components, a substrate, a main lead, and a sealing resin. The semiconductor chip includes a functional circuit. The plurality of passive electronic components assist a function of the semiconductor chip. The substrate has a principal surface and a reverse surface that face in opposite directions to each other, and the semiconductor chip and the plurality of passive electronic components are mounted on the principal surface. The main lead includes an island portion that is joined to the reverse surface of the substrate, and a terminal portion that is offset in a predetermined direction with respect to the island portion. The sealing resin covers the semiconductor chip, the substrate, and the island portion of the main lead.

### BACKGROUND OF THE INVENTION

1. Field of the Invention

The present invention relates to a semiconductor device.

2. Description of Related Art

Converters for converting input power to power appropriate for internal constituent elements are used in various electronic apparatuses. For example, a DC/DC converter converts input DC power to DC power having a desired voltage or current by switching control, and outputs the converted power. JP-A-2013-141035 discloses an example of a semiconductor device configured as a DC/DC converter. The semiconductor device includes a semiconductor chip, a lead on which the semiconductor chip is mounted, and a sealing resin that covers the semiconductor chip and the lead. The lead includes a plurality of terminal portions that protrude from the sealing resin. The semiconductor device converts the DC power that is input from one of the plurality of terminal portions to DC power having a desired voltage or current using the function of the semiconductor chip. Then, the converted DC power is output from one of the plurality of terminal portions.

A three-terminal regulator is one type of the converter that has a function of lowering a voltage of the input DC power to DC power having a predetermined voltage. Generally, three-terminal regulators have a relatively low conversion efficiency, since energy corresponding to the amount of change in voltage is converted to heat. Therefore, a low loss three-terminal regulator referred to as a LDO (Low Drop Out) type three-terminal regulator has been developed for the purpose of improving efficiency.

In electronic apparatuses in which LDO type three-terminal regulators are used, further improvement in efficiency, adapting to standards that are newly provided, and the like may be required. Aiming to meet such a requirement, a demand for replacing LDO type three-terminal regulators with DC/DC converters is expected. In order to realize such replacement, in addition to a semiconductor chip that performs switching control of the DC/DC converter, a plurality of passive electronic components for assisting the function of the semiconductor chip need to be used. However, it is very difficult to mount these passive electronic components on existing circuit boards on which LDO type three-terminal regulators were mounted, due to limited space and the like. Also, heat is unavoidably generated by the plurality of passive components in addition to the semiconductor chip, and accordingly heat dissipation needs to be performed appropriately.

### SUMMARY OF THE INVENTION

The present invention was conceived under the above circumstances. A main object of the present invention is to provide a semiconductor device that incorporates a semiconductor chip and a plurality of passive electronic components and enables miniaturization and improved heat dissipation.

A semiconductor device provided according to a first aspect of the invention includes: a semiconductor chip including a functional circuit; a plurality of passive electronic components that assist a function of the semiconductor chip; a substrate including a principal surface and a reverse surface that face in opposite directions to each other, and in which the semiconductor chip and the plurality of passive electronic components are mounted on the principal surface; a main lead including an island portion joined to the reverse surface of the substrate, and a terminal portion located on one side in a first direction relative to the island portion; and a sealing resin that covers the semiconductor chip, the substrate, and the island portion of the main lead.

It is preferable that the semiconductor chip and all of the plurality of electronic components are mounted on the substrate.

It is preferable that the plurality of passive electronic components include a coil.

In one embodiment, the coil generates a largest amount of heat among the plurality of passive electronic components.

It is preferable that the coil is located between the semiconductor chip and the terminal portion in the first direction.

It is preferable that the plurality of passive electronic components include a capacitor.

It is preferable that the capacitor is located between the semiconductor chip and the terminal portion in the first direction.

It is preferable that the plurality of passive electronic components include a plurality of capacitors, and the capacitor having a largest capacitance among the capacitors is arranged closest to the terminal portion in the first direction.

It is preferable that the substrate has a base made of an insulating material and including the principal surface and the reverse surface, and a principal surface wiring pattern formed on the principal surface of the base.

It is preferable that the substrate has a reverse surface wiring pattern formed on the reverse surface of the base.

It is preferable that the substrate has a through conductive portion that electrically connects the principal surface pattern and the reverse surface wiring pattern, and passes through the base.

It is preferable that a resist layer that covers the reverse surface wiring pattern is included.

It is preferable that the base is made of a ceramic.

It is preferable that the island portion is larger than the substrate in plan view.

It is preferable that the island portion and the substrate are rectangular in plan view.

It is preferable that the substrate is arranged close to the terminal portion in the first direction relative to the island portion.

It is preferable that a side, of the island portion, to which the terminal portion is connected and a side of the substrate coincide in plan view.

It is preferable that the semiconductor device includes a plurality of sub leads that respectively have terminal portions arrayed with the terminal portion of the main lead in a second direction that intersects the first direction.

It is preferable that the terminal portion of the main lead is provided between the terminal portions of two of the sub leads.

It is preferable that the terminal portion of the main lead is a ground terminal, and terminal portions of the plurality of sub leads include an input terminal and an output terminal.

It is preferable that the terminal portion of the main lead is arranged at a furthest end in the second direction relative to the plurality of sub leads.

It is preferable that the terminal portion of the main lead is provided closer, in the second direction, to the component that generates a largest amount of heat among the plurality of passive electronic components than are the plurality of sub leads.

It is preferable that the terminal portion of the main lead is an output terminal, and terminal portions of the plurality of sub leads includes an input terminal and a ground terminal.

In one embodiment, the semiconductor device functions as a DC/DC converter.

According to the present invention, the semiconductor chip and the plurality of passive electronic components are mounted on the substrate. Denser conduction paths can be configured in the substrate, compared with conduction paths configured only by leads, for example. Accordingly, the semiconductor chip and the plurality of passive electronic components can be arranged more compactly. Also, since the substrate is joined to the island portion of the main lead, heat generated by the semiconductor chip and the plurality of passive electronic components is conducted to the island portion via the substrate. The heat conducted to the substrate diffuses inside the substrate, and is also dissipated outside via the sealing resin. Even supposing that the semiconductor chip or any of the plurality of passive electronic components generates a considerable amount of heat, the heat can be diffused in the island portion. As a result, it is possible to avoid an unreasonably large temperature increase in part of the substrate. Thus, miniaturization and improved heat dissipation of the semiconductor device A1 can be realized.

Further features and advantages of the present invention will become apparent from the following detailed description with reference to the accompanying drawings.

### BRIEF DESCRIPTION OF THE DRAWINGS

FIG. 1 is a plan view illustrating a semiconductor device based on a first embodiment according to the present invention.

FIG. 2 is a cross-sectional view taken along line II-II in FIG. 1.

FIG. 3 is a cross-sectional view taken along line III-III in FIG. 1.

FIG. 4 is a cross-sectional view taken along line IV-IV in FIG. 1.

FIG. 5 is a plan view illustrating a substrate of the semiconductor device in FIG. 1.

FIG. 6 is a plan view illustrating a reverse surface wiring pattern of the substrate in FIG. 5.

FIG. 7 is a circuit diagram illustrating the semiconductor device in FIG. 1.

FIG. 8 is a plan view illustrating a semiconductor device based on a second embodiment according to the present invention.

FIG. 9 is a plan view illustrating a semiconductor device based on a third embodiment according to the present invention.

FIG. 10 is a cross-sectional view taken along line X-X in FIG. 9.

FIG. 11 is a cross-sectional view taken along line XI-XI in FIG. 9.

FIG. 12 is a cross-sectional view taken along line XII-XII in FIG. 9.

FIG. 13 is a plan view illustrating a substrate of the semiconductor device in FIG. 9.

FIG. 14 is a plan view illustrating a reverse surface wiring pattern of the substrate in FIG. 13.

FIG. 15 is a circuit diagram illustrating the semiconductor device in FIG. 9.

FIG. 16 is a plan view illustrating a semiconductor device based on a fourth embodiment according to the present invention.

### DESCRIPTION OF THE PREFERRED EMBODIMENTS

Hereinafter, preferred embodiments of the present invention will be specifically described with reference to the drawings.

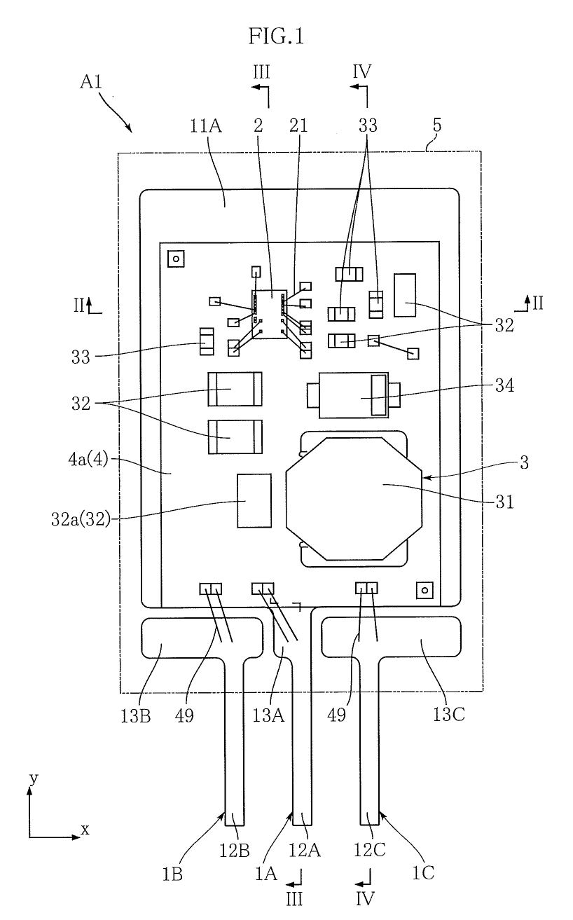

FIGS. 1 to 4 illustrate a semiconductor device based on a first embodiment according to the present invention. The semiconductor device A1 according to the present embodiment includes a main lead 1A, a sub lead 1B, a sub lead 1C, a semiconductor chip 2, a plurality of passive electronic components 3, a substrate 4, and a sealing resin 5. The sealing resin 5 is shown with a two-dot chain line in FIG. 1. Also, the thickness direction of the substrate 4 is given as a z direction in these diagrams. An x direction and a y direction are orthogonal to each other, and are both orthogonal to the z direction.

The semiconductor device A1 is configured as a DC/DC converter, but the present invention is not limited thereto. The semiconductor device A1 has an input voltage range of 8 V to 30 V, an output voltage range of 1.8 V to 5.0 V, and a maximum output current of 1000 mA, for example.

The main lead 1A includes an island portion 11A, a terminal portion 12A, and a pad portion 13A. The main lead 1A is made of a metal such as Cu, Ni, or Fe. The thickness of the main lead 1A is approximately 0.4 mm to 1.6 mm.

The island portion 11A is a portion to which the substrate 4 is joined, and is rectangular in plan view (viewed in the z direction) in the present embodiment. As an example, the size of the island portion 11A is 12 mm in the x direction and 15.7 mm in the y direction.

The terminal portion 12A protrudes in the y direction from the island portion 11A and extends along the y direction. The terminal portion 12A is used for mounting the semiconductor device A1 on a circuit board or the like of an electronic apparatus. The terminal portion 12A functions as a ground terminal in the present embodiment. The size of the terminal portion 12A in the x direction is approximately 0.7 mm, for example.

The pad portion 13A is provided in a base portion of the terminal portion 12A. In the illustrated example, one end of each of two wires 49 is bonded to the pad portion 13A. The other end of each wire 49 is connected to the substrate 4. The size of the pad portion 13A in the x direction is approximately 1 mm, for example, and the size in the y direction is approximately 2 mm, for example.

The sub lead 1B includes a terminal portion 12B and a pad portion 13C. The sub lead 1B is made of a metal such as Cu, Ni, or Fe. The thickness of the sub lead 1B is approximately 0.4 mm to 1.6 mm.

The terminal portion 12B is arranged in the left in the x direction relative to the terminal portion 12A of the main lead 1A in a state of being spaced therefrom, and extends in parallel to the terminal portion 12A (that is, along the y direction). The terminal portion 12B is used for mounting the semiconductor device A1 on a circuit board or the like of an electronic apparatus. In the present embodiment, the terminal portion 12B functions as an input terminal. The size of the terminal portion 12B in the x direction is approximately 0.7 mm, for example.

The pad portion 13B is provided in a base portion of the terminal portion 12B. In the illustrated example, one end of each of two wires 49 is bonded to the pad portion 13B. The other end of each wire 49 are connected to the substrate 4. The size of the pad portion 13B in the x direction is approximately 4.5 mm, for example, and the size in the y direction is approximately 1.6 mm, for example.

The sub lead 1C includes a terminal portion 12C and a pad portion 13C. The sub lead 1C is made of a metal such as Cu, Ni, or Fe. The thickness of the sub lead 1C is approximately 0.4 mm to 1.6 mm.

The terminal portion 12C is arranged to the right in the x direction relative to the terminal portion 12A of the main lead 1A in a state of being spaced therefrom, and extends in parallel to the terminal portion 12A (that is, along the y direction). The terminal portion 12C is used for mounting the semiconductor device A1 on a circuit board or the like of an electronic apparatus. In the present embodiment, the terminal portion 12C functions as an output terminal. The size of the terminal portion 12B in the x direction is approximately 0.7 mm, for example.

The pad portion 13C is provided in a base portion of the terminal portion 12C. In the illustrated example, one end of each of two wires 49 is bonded to the pad portion 13C. The other end of each wire 49 are connected to the substrate 4. The size of the pad portion 13C in the x direction is approximately 5.3 mm, for example, and the size in the y direction is approximately 1.6 mm, for example.

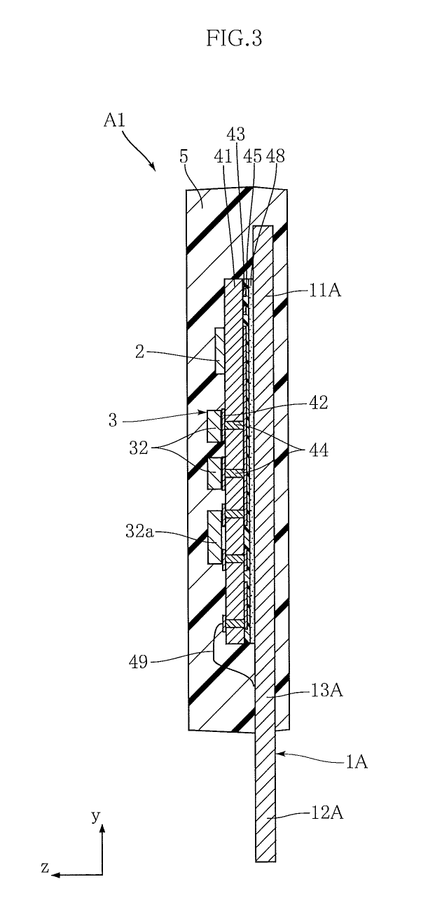

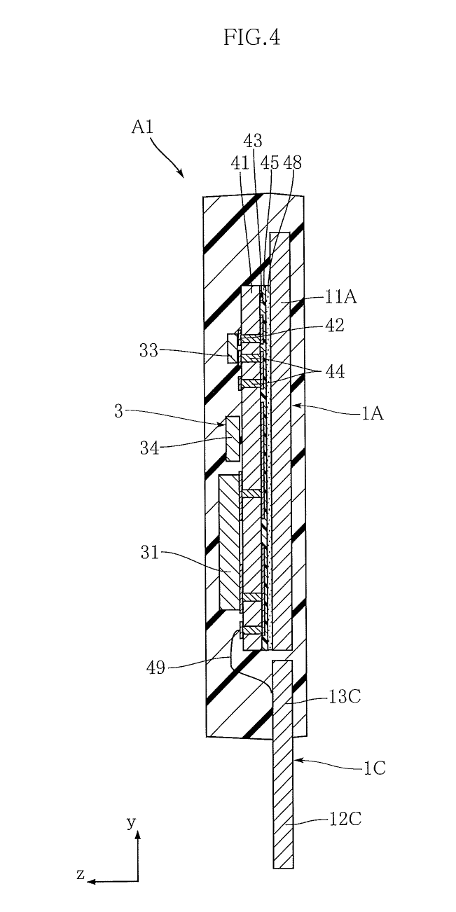

The main lead 1A, the sub lead 1B, and the sub lead 1C are each in parallel to the x-y plane as a whole (flat shape without a bent portion) (refer to FIGS. 3 and 4), and are arranged in the same position in the z direction.

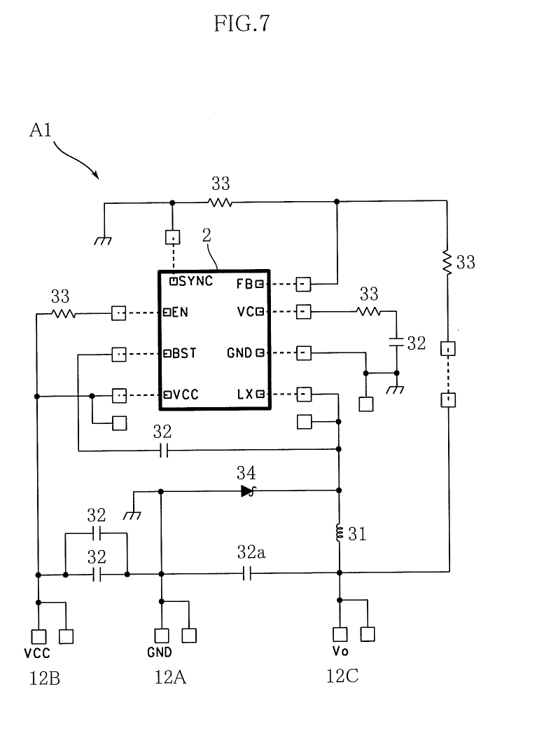

The semiconductor chip 2 includes a functional circuit that performs switching control in the DC/DC converter. FIG. 7 is a circuit diagram of the semiconductor device A1. As shown in the diagram, the semiconductor chip 2, in the present embodiment, includes a VCC (input) terminal, a BST (boost) terminal, an EN (enable) terminal, a SYNC (synchronization) terminal, a FB (feedback) terminal, a VC (error amplifier output) terminal, a GND (ground) terminal, and an LX (output) terminal.

As shown in FIG. 1, the semiconductor chip 2 is mounted on a principal surface 4a of the substrate 4, and is arranged close to an upper edge of the substrate 4. The VCC (input) terminal, the BST (boost) terminal, the EN (enable) terminal, the SYNC (synchronization) terminal, the FB (feedback) terminal, the VC (error amplifier output) terminal, the GND (ground) terminal, and the LX (output) terminal described above are divided into two groups that are respectively arranged on different sides of the semiconductor chip 2 in the x direction. The semiconductor chip 2 is joined to the principal surface 4a of the substrate 4 with an adhesive material such as an insulating paste or an Ag paste.

The plurality of passive electronic components 3 have a function of assisting the function of the semiconductor chip 2. The plurality of passive electronic components 3, in the present embodiment, includes a coil 31, a plurality of capacitors 32, a plurality of resistors 33, and a Schottky diode 34.

As shown in FIG. 7, the coil 31 is connected between the LX terminal and the terminal portion 12C. Also, as shown in FIG. 1, the coil 31 is arranged between the semiconductor chip 2 and the terminal portion 12A in the y direction. In the present embodiment, the terminal portion 12C is the closest to the coil 31 out of the terminal portion 12A, the terminal portion 12B, and the terminal portion 12C. The coil 31 generates the largest amount of heat among the plurality of passive electronic components 3. Also, the coil 31 has the largest size in plan view among the plurality of passive electronic components 3.

The plurality of capacitors 32 and 32a are each arranged at an appropriate position shown in FIG. 7, and are each in a predetermined connection state. These capacitors 32 mainly perform a function of noise removal or the like. Specifically, the capacitor 32a is connected between the terminal portion 12A and the terminal portion 12C, and has a larger capacitance than the other capacitors 32. As shown in FIG. 1, the capacitor 32a is arranged close to the terminal portion 12A in the y direction than the other capacitors 32. The capacitance of the capacitor 32a is 10 μF, for example, and the capacitance of each of the other capacitors 32 is 0.068 μF to 1.0 μF, for example.

The plurality of resistors 33 are each arranged at an appropriate position shown in FIG. 7, and are each in a predetermined connection state. These resistors 33 perform a function of adjusting voltage or current, or the like.

The Schottky diode 34 is connected between the terminal portion 12A and the terminal portion 12C in parallel to the capacitor 32a, as shown in FIG. 7.

The substrate 4 on which the semiconductor chip 2 and the plurality of passive electronic components 3 are mounted includes a base 41, a principal surface wiring pattern 42, a reverse surface wiring pattern 43, and a plurality of through conductive portions 44. Also, the substrate 4 has a principal surface 4a and a reverse surface 4b that are spaced from each other in the direction.

In the present embodiment, the substrate 4 is rectangular when viewed in the z direction. The substrate 4 has a size of 10.5 mm, for example, in the x direction, a size of 13.7 mm in the y direction, and a thickness of 0.635 mm, for example, in the z direction. Also, as shown in FIG. 1, the substrate 4 is arranged close to the terminal portion 12A relative to the island portion 11A of the main lead 1A. Also, the lower edge (extending in the x direction) of the substrate 4 in the diagram when viewed in the z direction coincides with a side (located in a lower part of the diagram) from which the terminal portion 12A protrudes, out of the four sides of the island portion 11A.

At least a surface of the base 41 is made of an insulating material. Insulating materials include a ceramic or a glass epoxy resin, for example. The entirety of the base 41 may be made of the insulating material. A base 41 in which only the surface thereof has insulation properties can be obtained by insulating a surface of an aluminum plate, for example. The base 41 is made of a ceramic in the present embodiment.

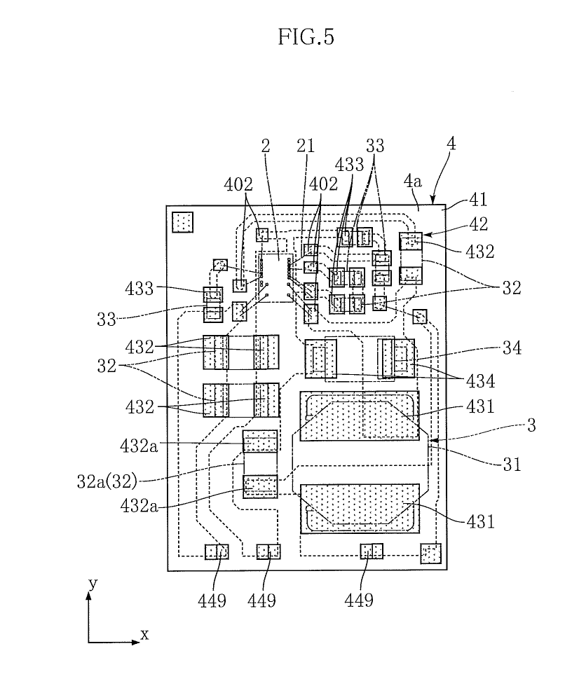

The principal surface wiring pattern 42 is formed on the principal surface 4a of the base 41 and is constituted by a plated layer made of Cu, Ni, Au, or the like. The principal surface wiring pattern 42 includes a plurality of pad portions 402, 431, 432, 432a, 433, 434, and 449, as shown in FIG. 5.

The plurality of pad portions 402 are arranged so as to surround the semiconductor chip 2, and are respectively connected to the VCC (input) terminal, the BST (boost) terminal, the EN (enable) terminal, the SYNC (synchronization) terminal, the FB (feedback) terminal, the VC (error amplifier output) terminal, the GND (ground) terminal, and the LX (output) terminal of the semiconductor chip 2, via respective wires 21.

The two pad portions 431 are arranged so as to be spaced from each other in the y direction. The coil 31 is joined to the two pad portions 431 by solder, for example.

The plurality of pad portions 432 are arranged so as to form pairs of two pads. One capacitor 32 is joined to each pair of pad portions 432 by solder, for example. The capacitor 32a is joined to the pair of pad portions 432a that is closest to the terminal portion 12A in the y direction.

The plurality of pad portions 433 are arranged so as to form pairs of two pads. One resistor 33 is joined to each pair of pad portions 433 by solder, for example.

The two pad portions 434 are arranged so as to be spaced from each other in the x direction above the two pad portions 431 in the y direction in the diagram. A Schottky diode 34 is joined to the two pad portions 434 by solder, for example.

The plurality of pad portions 449 are arranged in the vicinity of the lower edge of the substrate 4 in the y direction in the diagram. In the present embodiment, the plurality of pad portions 449 are arranged so as to form pairs in each of which two pads are arranged adjacent to each other. The pairs of pad portions 449 are respectively arranged adjacent to the terminal portion 12A, the terminal portion 12B, and the terminal portion 12C. Wires 49 shown in FIG. 1 extend to the pad portion 13A, the pad portion 13B, and the pad portion 13C from respective pairs of pad portions 449.

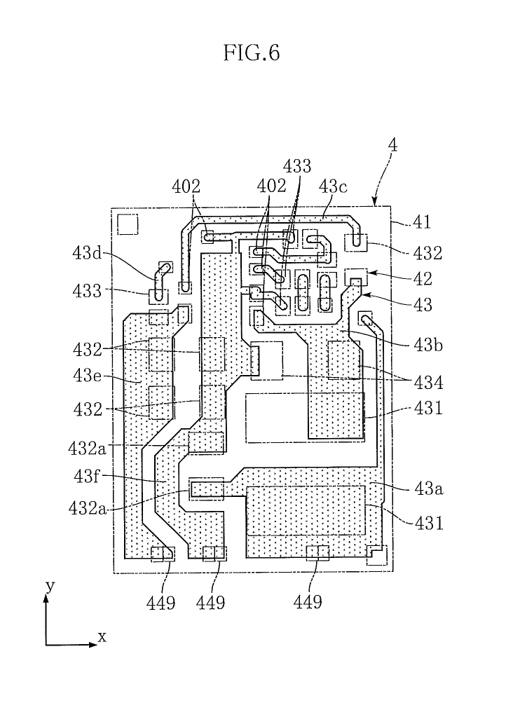

FIG. 6 is a see-through plan view of the substrate 4 viewed from the principal surface 4a side, and the reverse surface wiring pattern 43 is shown with a solid line viewed through the base 41 and the principal surface wiring pattern 42. The reverse surface wiring pattern 43 is formed on the reverse surface 4b of the substrate 4 and is constituted by a plated layer made of Cu, Ni, Au, or the like.

The reverse surface wiring pattern 43 includes a path 43a, a path 43b, a path 43c, a path 43d, a path 43e, and a path 43f. The path 43a, when viewed in the z direction, overlaps with the pad portion 431 and the pad portion 432a of the principal surface wiring pattern 42, overlaps with another portion of the principal surface wiring pattern 42, and electrically connects these portions via the through conductive portions 44. The path 43b overlaps with the pad portion 431, the pad portion 432, and the pad portion 402 of the principal surface wiring pattern 42, and electrically connects these portions via the through conductive portions 44. The path 43c overlaps with the pad portion 402 and the pad portion 432 of the principal surface wiring pattern 42, when viewed in the z direction, and electrically connects these portions via the through conductive portions 44. The path 43d overlaps with the pad portion 433 and another portion of the principal surface wiring pattern 42 in plan view, and electrically connects these portions via the through conductive portions 44. The path 43e overlaps with the pad portion 432, the pad portion 433, and the pad portion 449 in plan view, and electrically connects these portions via the through conductive portions 44. The path 43f overlaps with the pad portion 402, the pad portion 432a, the pad portion 433, the pad portion 432, the pad portion 434, and the pad portion 449 in plan view, and electrically connects these portions via the through conductive portions 44.

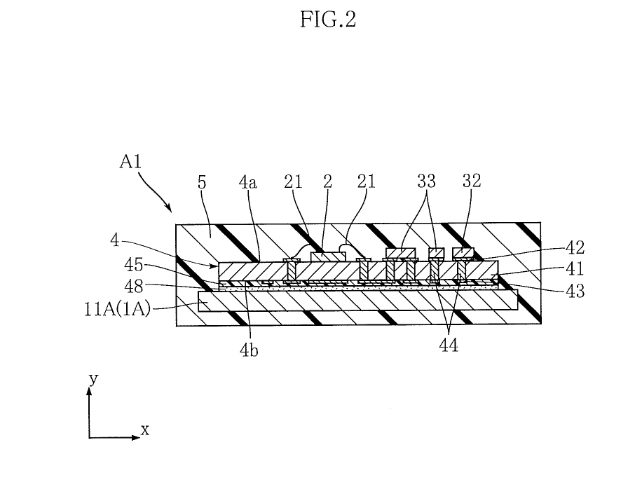

The plurality of through conductive portions 44 each pass through the base 41 and electrically connect an appropriate portion of the principal surface wiring pattern 42 and an appropriate portion of the reverse surface wiring pattern 43, as shown in FIGS. 2 to 4. The material of the through conductive portions 44 is the same as the material of the principal surface wiring pattern 42 and the reverse surface wiring pattern 43, for example.

The resist layer 45 covers the reverse surface wiring pattern 43 and is made of an insulating resin. The resist layer 45 may cover the whole reverse surface 4b of the substrate 4, or may cover a partial region, which includes the whole reverse surface wiring pattern 43, of the reverse surface 4b.

The reverse surface 4b of the substrate 4 is joined to the island portion 11A via a junction layer 48. The junction layer 48 may be an insulating adhesive layer or a conductive adhesive layer. The junction layer 48 preferably includes a metal as the main component in order to improve heat conductivity from the substrate 4 to the main lead 1A.

The sealing resin 5 covers parts of the respective main lead 1A, sub lead 1B, and sub lead 1C, the semiconductor chip 2, the plurality of passive electronic components 3, and the substrate 4. The sealing resin 5 is made of a black epoxy resin, for example. In the present embodiment, the sealing resin 5 covers the whole reverse surface of the island portion 11A.

Next, the function of the semiconductor device A1 will be described.

According to the present embodiment, the semiconductor chip 2 and the plurality of passive electronic components 3 are mounted on the substrate 4. Denser conduction paths can be configured on the substrate 4, compared with conduction paths configured only by leads. Accordingly, the semiconductor chip 2 and the plurality of passive electronic components 3 can be arranged more compactly. Also, as a result of the substrate 4 being joined to the island portion 11A of the main lead 1A, heat that is generated in the semiconductor chip 2 and the plurality of passive electronic components 3 is conducted to the island portion 11A via the substrate 4. The heat that is conducted to the substrate 4 diffuses inside the substrate 4, and is also dissipated outside via the sealing resin 5. Even supposing the semiconductor chip 2 or any of the plurality of passive electronic components 3 generates a considerable amount of heat, the heat can be diffused in the island portion 11A. As a result, it is possible to avoid an unreasonably large temperature increase in part of the substrate 4. Thus, miniaturization and improved heat dissipation of the semiconductor device A1 can be realized.

For the purpose of improving efficiency of an electronic apparatus, adapting to standards in the country where the electronic apparatus is used, and the like, the semiconductor device A1 can be mounted on an existing circuit board of an electronic apparatus that included an LDO type three-terminal regulator, in place of the three-terminal regulator. The semiconductor device A1 includes not only the semiconductor chip 2, but also the coil 31 and the plurality of capacitors 32 including the capacitor 32a. Accordingly, a coil or capacitors of input and output sides need not be mounted on the circuit board in addition to the semiconductor device A1. Therefore, an LDO type three-terminal regulator can be replaced with the semiconductor device A1 with a very simple operation.

Since the semiconductor chip 2 and the plurality of passive electronic components 3 are all mounted on the substrate 4, conduction paths for electrically connecting these components can be configured more densely.

By providing the coil 31 that generates the largest amount of heat close to the terminal portion 12A, the heat from the coil 31 can be more smoothly dissipated outside from the terminal portion 12A. Also, by arranging the coil 31 between the semiconductor chip 2 and the terminal portion 12C, loss on a path from the semiconductor chip 2 via the coil 31 can be reduced.

By providing the capacitor 32a having the largest capacitance close to the terminal portion 12A and the terminal portion 12B, a function such as noise removal can be exhibited appropriately without setting the capacitor 32a to an excessively large capacitance.

As a result of the substrate 4 including the principal surface wiring pattern 42, the reverse surface wiring pattern 43, and the plurality of through conductive portions 44, conduction paths in which portions of the wiring patterns overlap each other when viewed in the z direction can be configured. This is suitable for arranging the semiconductor chip 2 and the plurality of passive electronic components 3 more compactly when viewed in the z direction.

As a result of the base 41 being made of a ceramic, heat from the semiconductor chip 2 and the plurality of coils 31 can be conducted to the island portion 11A more smoothly. Also, the base 41 has an advantage in that the thermal expansion thereof is relatively small and there is little deformation during use.

As a result of the edge side of the substrate 4 in the y direction coinciding with the lower edge side of the island portion 11A in the y direction from which the terminal portion 12A protrudes, as shown in FIG. 1, the lengths of the wires 49 that connect the substrate 4 to the pad portion 13A, the pad portion 13B, and the pad portion 13C can be reduced. This contributes to reduction of the resistance.

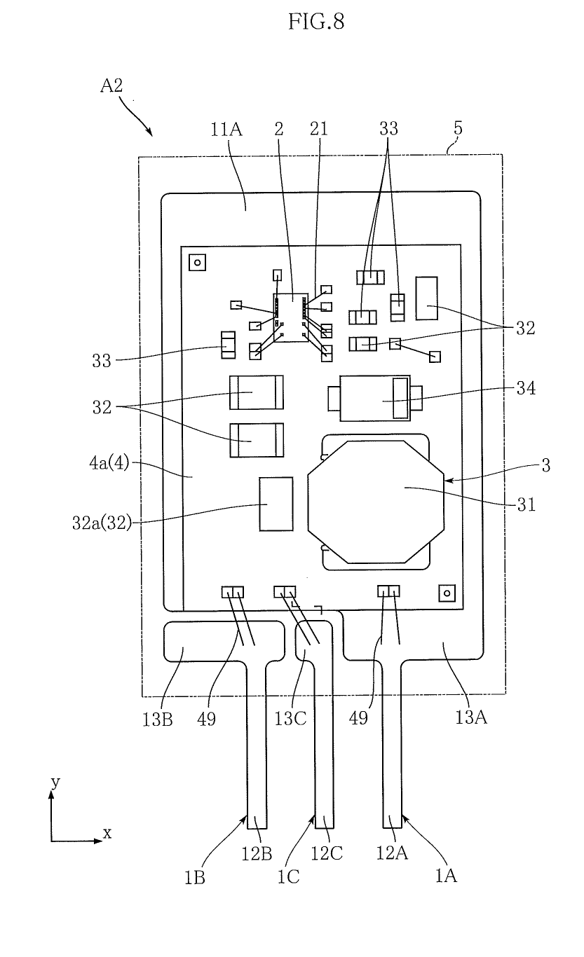

FIGS. 8 to 16 show modifications and other embodiments according to the present invention. Note that, in these diagrams, the same reference signs as the above embodiment are given to elements that are the same as or similar to the above embodiment.

FIG. 8 shows a semiconductor device based on a second embodiment of the present invention. In A2 of the present embodiment, a terminal portion 12A of a main lead 1A is arranged at the right end in the x direction in the diagram relative to a terminal portion 12B of a sub lead 1B and a terminal portion 12C of a sub lead 1C. Also, the terminal portion 12A is arranged closest to a coil 31 in the x direction, the coil 31 generating the largest amount of heat among a plurality of passive electronic components 3.

In the present embodiment, the terminal portion 12C functions as a ground terminal, the terminal portion 12B functions as an input terminal, and the terminal portion 12A functions as an output terminal. The remaining configuration of the semiconductor device A2 is in common with the aforementioned semiconductor device A1.

According to this embodiment as well, miniaturization and improved heat dissipation of the semiconductor device A2 can be realized. Also, the terminal portion 12A that is connected to the island portion 11A is arranged close to the coil 31 than are the terminal portion 12B and the terminal portion 12C. Accordingly, the heat from the coil 31 that generates the largest amount of heat can be more smoothly dissipated outside via the terminal portion 12A.

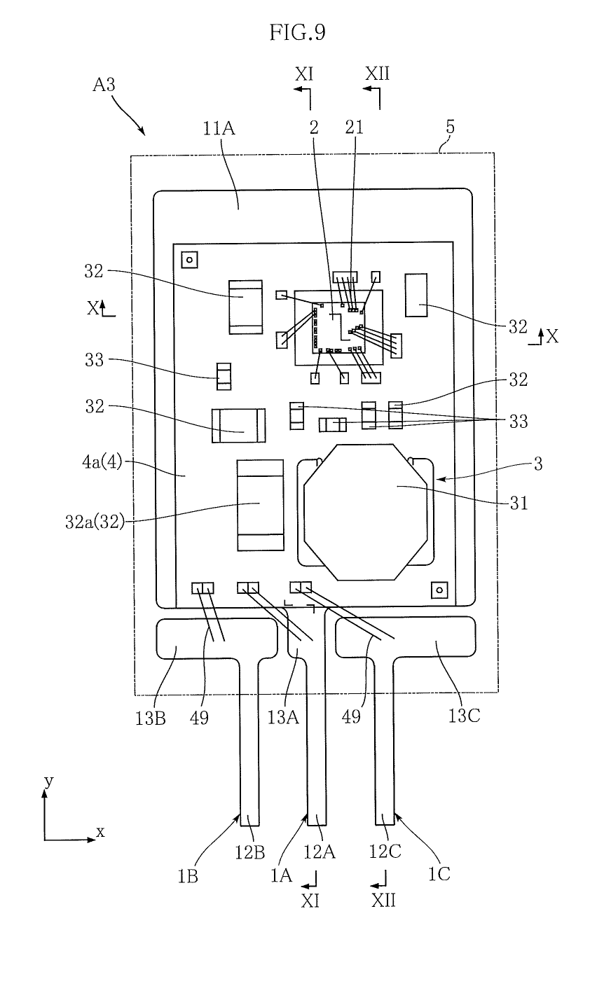

FIGS. 9 to 12 show a semiconductor device based on a third embodiment of the present invention. A semiconductor device A3 according to the present embodiment includes a main lead 1A, a sub lead 1B, a sub lead 1C, a semiconductor chip 2, a plurality of passive electronic components 3, a substrate 4, and a sealing resin 5.

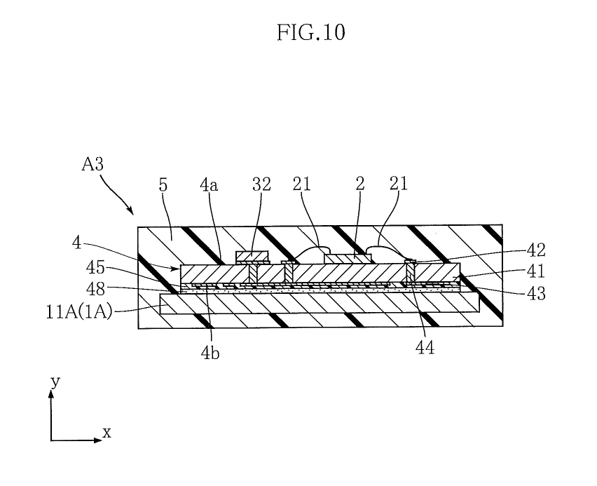

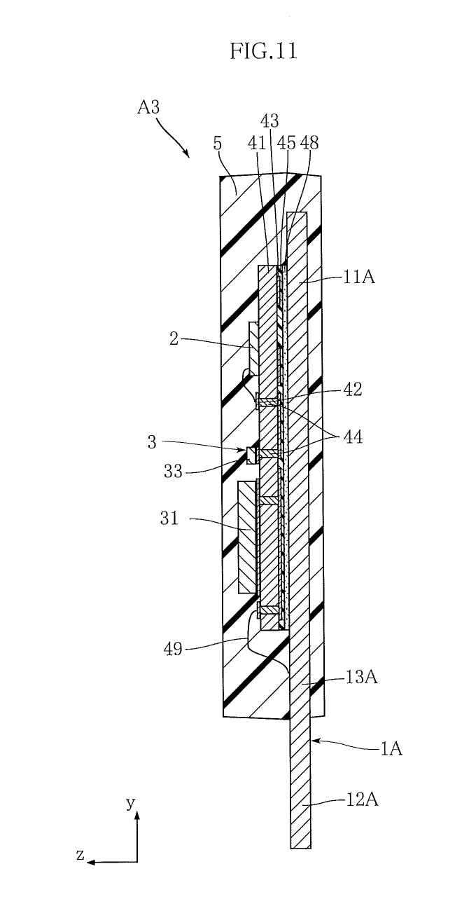

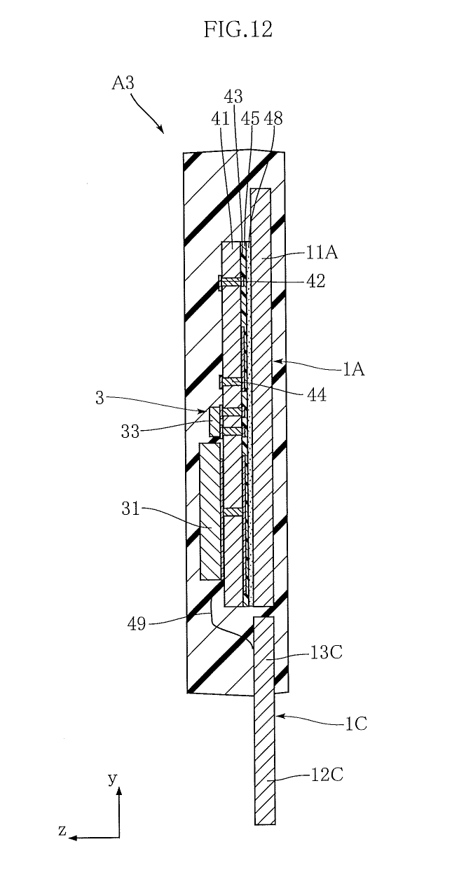

FIG. 9 is a plan view illustrating the semiconductor device A3. FIG. 10 is a cross-sectional view taken along line X-X in FIG. 9. FIG. 11 is a cross-sectional view taken along line XI-XI in FIG. 9. FIG. 12 is a cross-sectional view taken along line XII-XII in FIG. 9. Note that, in FIG. 9, the sealing resin 5 is shown with an imaginary line to facilitate understanding. Also, the z direction is the thickness direction of the substrate 4 in these diagrams. The x direction and the y direction are both orthogonal to the z direction and are orthogonal to each other.

The semiconductor device A3 is configured as a so-called DC/DC converter. An example of usage of the semiconductor device A3 is in an input voltage range of 8 V to 30 V, an output voltage of 12 V, and a maximum output current of 1000 mA.

The main lead 1A includes an island portion 11A, a terminal portion 12A, and a pad portion 13A. The main lead 1A is made of a metal such as Cu, Ni, or Fe. The thickness of the main lead 1A is approximately 0.4 mm to 1.6 mm.

The island portion 11A is a portion to which the substrate 4 is joined, and is rectangular in plan view (viewed in the z direction) in the present embodiment. As an example, the size of the island portion 11A is 12 mm in the x direction and 15.7 mm in the y direction.

The terminal portion 12A protrudes to one side in the y direction from the island portion 11A and extends along the y direction. The terminal portion 12A is used for mounting the semiconductor device A3 on a circuit board or the like of an electronic apparatus. The terminal portion 12A functions as a ground terminal in the present embodiment. The size of the terminal portion 12A in the x direction is approximately 0.7 mm, for example.

The pad portion 13A is provided in a base portion of the terminal portion 12A. The pad portion 13A is a portion to which one end of a wire 49 whose other end is connected to the substrate 4 is bonded. The size of the pad portion 13A in the x direction is approximately 1 mm, for example, and the size in the y direction is approximately 2 mm, for example.

The sub lead 1B includes a terminal portion 12B and a pad portion 13C. The sub lead 1B is made of a metal such as Cu, Ni, or Fe. The thickness of the sub lead 1B is approximately 0.4 mm to 1.6 mm.

The terminal portion 12B is arranged to the left in the x direction in the diagram relative to the terminal portion 12A of the main lead 1A in a state of being spaced therefrom, and extends in parallel to the terminal portion 12A along the y direction. The terminal portion 12B is used for mounting the semiconductor device A3 on a circuit board or the like of an electronic apparatus. In the present embodiment, the terminal portion 12B functions as an input terminal. The size of the terminal portion 12B in the x direction is approximately 0.7 mm, for example.

The pad portion 13B is provided above the terminal portion 12B in the y direction in the diagram. The pad portion 13B is a portion to which one end of a wire 49 whose other end is connected to the substrate 4 is bonded. The size of the pad portion 13B in the x direction is approximately 4.5 mm, for example, and the size in the y direction is approximately 1.6 mm, for example.

The sub lead 1C includes a terminal portion 12C and a pad portion 13C. The sub lead 1C is made of a metal such as Cu, Ni, or Fe. The thickness of the sub lead 1C is approximately 0.4 mm to 1.6 mm.

The terminal portion 12C is arranged to the right in the x direction in the diagram relative to the terminal portion 12A of the main lead 1A in a state of being spaced therefrom, and extends in parallel to the terminal portion 12A along the y direction. The terminal portion 12C is used for mounting the semiconductor device A3 on a circuit board or the like of an electronic apparatus. In the present embodiment, the terminal portion 12C functions as an output terminal. The size of the terminal portion 12B in the x direction is approximately 0.7 mm, for example.

The pad portion 13C is provided above the terminal portion 12C in the y direction in the diagram. The pad portion 13C is a portion to which one end of a wire 49 whose other end is connected to the substrate 4 is bonded. The size of the pad portion 13C in the x direction is approximately 5.3 mm, for example, and the size in the y direction is approximately 1.6 mm, for example.

The main lead 1A, the sub lead 1B, and the sub lead 1C each have a flat shape when viewed in the x direction and y direction without a bent portion or the like, and the positions thereof in the z direction coincide with each other.

The semiconductor chip 2 includes a functional circuit that performs switching control in the DC/DC converter. FIG. 7 is a circuit diagram of the semiconductor device A1. As shown in the diagram, the semiconductor chip 2, in the present embodiment, includes a BOOT (boot) terminal, a VIN (input) terminal, an EN (enable) terminal, an AGND (ground) terminal, a FB (feedback) terminal, a COMP (comparison voltage) terminal, a PGND (ground) terminal, and an SW (switching) terminal.

As shown in FIG. 9, the semiconductor chip 2 is mounted on a principal surface 4a of the substrate 4, and is arranged close to an upper side in the y direction in the diagram. The BOOT (boot) terminal, the VIN (input) terminal, the EN (enable) terminal, the AGND (ground) terminal, the FB (feedback) terminal, the COMP (comparison voltage) terminal, the PGND (ground) terminal, and the SW (switching) terminal described above are arranged in a circle along the four sides of the semiconductor chip 2. The semiconductor chip 2 is joined to the principal surface 4a of the substrate 4 with an adhesive material such as an insulating paste or an Ag paste.

The plurality of passive electronic components 3 have a function of assisting the function of the semiconductor chip 2. The plurality of passive electronic components 3, in the present embodiment, includes a coil 31, a plurality of capacitors 32, and a plurality of resistors 33.

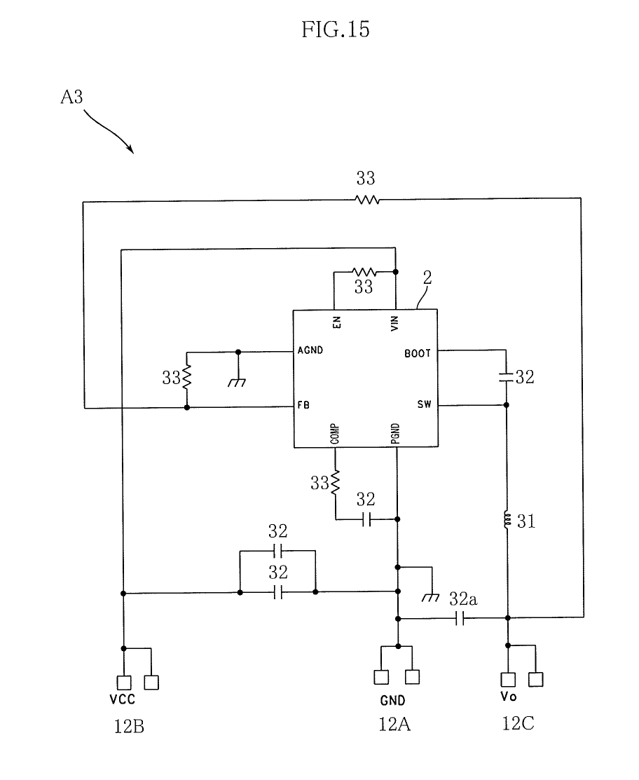

As shown in FIG. 15, the coil 31 is connected between the terminal portion 12C and the BOOT terminal and SW terminal. Also, as shown in FIG. 9, the coil 31 is arranged between the semiconductor chip 2 and the terminal portion 12A in the y direction. In the present embodiment, the terminal portion 12C is the closest to the coil 31 out of the terminal portion 12A, the terminal portion 12B, and the terminal portion 12C. The coil 31 is a component that generates the largest amount of heat among the plurality of passive electronic components 3. Also, the coil 31 has the largest size in plan view among the plurality of passive electronic components 3.

The plurality of capacitors 32 are each connected to appropriate portions shown in FIG. 15, and mainly perform a function of noise removal or the like. Specifically, the capacitor 32a connected between the terminal portion 12A and the terminal portion 12C has a larger capacitance than the other capacitors 32. As shown in FIG. 9, the capacitor 32a is arranged closer to the terminal portion 12A in the y direction than are the other capacitors 32. The capacitance of the capacitor 32a is 22 μF, for example, and the capacitance of each of the other capacitors 32 is 0.068 μF to 1.0 μF, for example.

The plurality of resistors 33 are each connected to appropriate portions shown in FIG. 15, and perform a function of adjusting voltage or current, or the like.

The substrate 4 on which the semiconductor chip 2 and the plurality of passive electronic components 3 are mounted includes a base 41, a principal surface wiring pattern 42, a reverse surface wiring pattern 43, and a plurality of through conductive portions 44. Also, the substrate 4 has a principal surface 4a and a reverse surface 4b that face in opposite directions to each other in the z direction.

In the present embodiment, the substrate 4 is rectangular when viewed in the z direction. The substrate 4 has a size of 10.5 mm, for example, in the x direction, and a size of 13.7 mm in the y direction, and a thickness of 0.635 mm, for example, in the z direction. Also, as shown in FIG. 9, the substrate 4 is arranged at a lower side in the y direction in the diagram relative to the island portion 11A of the main lead 1A (close to the terminal portion 12A). Also, the lower side of the substrate 4 in the y direction in the diagram when viewed in the z direction coincides with a side (located at a lower side in the y direction in the diagram) from which the terminal portion 12A protrudes, among the four sides of the island portion 11A.

The base 41 is made of an insulating material in which at least a surface thereof is in an insulated state, and is formed by a ceramic, a glass epoxy resin, an aluminum plate whose surfaced has been insulated, or the like, for example. In the present embodiment, the case where the base 41 is made of a ceramic will be described as an example.

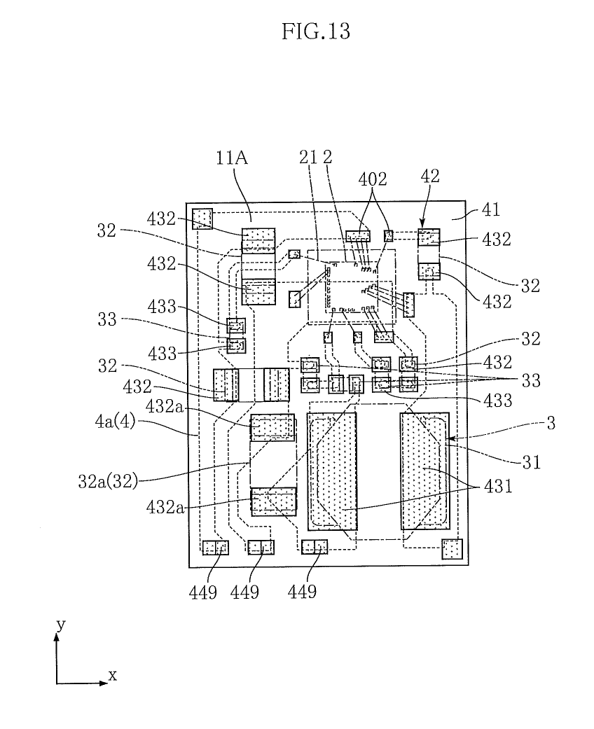

The principal surface wiring pattern 42 is formed on the principal surface 4a of the base 41 and is constituted by a plated layer made of Cu, Ni, Au, or the like. FIG. 13 is a plan view of the substrate 4. As shown in the diagram, the principal surface wiring pattern 42 includes a plurality of pad portions 402, pad portions 431, pad portions 432, pad portions 432a, pad portions 433, and pad portions 449.

The plurality of pad portions 402 are arranged so as to surround the semiconductor chip 2, and are respectively connected to the BOOT (boot) terminal, the VIN (input) terminal, the EN (enable) terminal, the AGND (ground) terminal, the FB (feedback) terminal, the COMP (comparison voltage) terminal, the PGND (ground) terminal, and the SW (switching) terminal of the semiconductor chip 2, via respective wires 21.

The two pad portions 431 are arranged so as to be spaced from each other in the y direction. The coil 31 is joined to the two pad portions 431 by solder, for example.

The plurality of pad portions 432 are arranged so as to form pairs of two pads. A capacitor 32 is joined to each pair of pad portions 432 by solder, for example. A capacitor 32a is joined to the pair of pad portions 432a that is closest to the terminal portion 12A in the y direction.

The plurality of pad portions 433 are arranged so as to form pairs of two pads. A resistor 33 is joined to each pair of pad portions 433 by solder, for example.

The plurality of pad portions 449 are arranged in the vicinity of the lower end of the substrate 4 in the y direction in the diagram. The plurality of pad portions 449 are arranged so as to form pairs in each of which two pads are arranged adjacent to each other in the present embodiment. The pairs of pad portions 449 are respectively arranged adjacent to the terminal portion 12A, the terminal portion 12B, and the terminal portion 12C. Wires 49 shown in FIG. 9 extend to the pad portion 13A, pad portion 13B, and the pad portion 13C from respective pairs of pad portions 449.

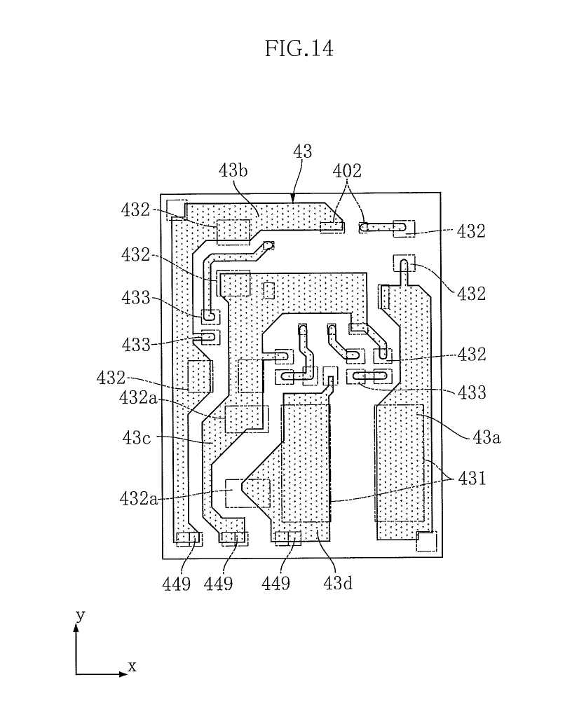

FIG. 14 is a see-through plan view of the substrate 4 viewed from the principal surface 4a side, and a reverse surface wiring pattern 43 is shown with a solid line viewed through the base 41 and the principal surface wiring pattern 42. The reverse surface wiring pattern 43 is formed on the reverse surface 4b of the substrate 4 and is constituted by a plated layer made of Cu, Ni, Au, or the like.

The reverse surface wiring pattern 43 includes a path 43a, a path 43b, a path 43c, and a path 43d. The path 43a overlaps, when viewed in the z direction, with a pad portion 431 and a pad portion 432 of the principal surface wiring pattern 42, and electrically connects these portions via through conductive portions 44. The path 43b overlaps with a pad portion 402, pad portions 432 and a pad portion 449 of the principal surface wiring pattern 42, and electrically connects these portions via the through conductive portions 44. The path 43c overlaps, when viewed in the z direction, with pad portions 432, a pad portion 432a, a pad portion 433, and a pad portion 449 of the principal surface wiring pattern 42, and electrically connects these portions via the through conductive portions 44. The path 43d overlaps with a pad portion 431, a pad portion 433, and a pad portion 432a in plan view, and electrically connects these portions via the through conductive portions 44.

The plurality of through conductive portions 44 each pass through the base 41 and electrically connect an appropriate portion of the principal surface wiring pattern 42 and an appropriate portion of the reverse surface wiring pattern 43, as shown in FIGS. 10 to 12. The material of the through conductive portions 44 is the same as the material of the principal surface wiring pattern 42 and the material of the reverse surface wiring pattern 43, for example.

The resist layer 45 covers the reverse surface wiring pattern 43 and is made of insulating resin. The resist layer 45 may cover the whole reverse surface 4b of the substrate 4, or may cover a partial region, which includes the whole reverse surface wiring pattern 43, of the reverse surface 4b.

The reverse surface 4b of the substrate 4 is joined to the island portion 11A via a junction layer 48. The junction layer 48 may be an insulating adhesive layer or a conductive adhesive layer. The junction layer 48 preferably includes a metal as the main component in order to improve the thermal conductivity from the substrate 4 to the main lead 1A.

The sealing resin 5 covers part of each of the main lead 1A, the sub lead 1B, and the sub lead 1C, the semiconductor chip 2, the plurality of passive electronic components 3, and the substrate 4. The sealing resin 5 is made of a black epoxy resin, for example. In the present embodiment, the sealing resin 5 covers the whole reverse surface of the island portion 11A.

Next, the function of the semiconductor device A3 will be described.

According to the present embodiment, the semiconductor chip 2 and the plurality of passive electronic components 3 are mounted on the substrate 4. Denser conduction paths can be configured on the substrate 4, compared with conduction paths configured only by leads. Accordingly, the semiconductor chip 2 and the plurality of passive electronic components 3 can be arranged more compactly. Also, as a result of the substrate 4 being joined to the island portion 11A of the main lead 1A, heat that is generated in the semiconductor chip 2 and the plurality of passive electronic components 3 is conducted to the island portion 11A via the substrate 4. The heat that is conducted to the substrate 4 diffuses inside the substrate 4, and is also dissipated outside via the sealing resin 5. Even supposing that the semiconductor chip 2 or one of the plurality of passive electronic components 3 generates a considerable amount of heat, the heat can be diffused in the island portion 11A. As a result, it is possible to avoid the large local increase in the temperature of the substrate 4. Thus, miniaturization and improved heat dissipation of the semiconductor device A3 can be realized.

For the purpose of improving efficiency of an electronic apparatus, adapting to standards in the country where the electronic apparatus is used, and the like, the semiconductor device A3 can be mounted on an existing circuit board of an electronic apparatus that included an LDO type three-terminal regulator, in place of the three-terminal regulator. The semiconductor device A3 includes not only the semiconductor chip 2, but also the coil 31 and the plurality of capacitors 32 including the capacitor 32a. Accordingly, a coil or capacitors of input and output sides need not be mounted on the circuit board in addition to the semiconductor device A3. Therefore, an LDO type three-terminal regulator can be replaced with the semiconductor device A3 with a very simple operation.

Since the semiconductor chip 2 and the plurality of passive electronic components 3 are all mounted on the substrate 4, conduction paths for electrically connecting these components can be configured more densely.

By providing the coil 31 that generates the largest amount of heat close to the terminal portion 12A, the heat from the coil 31 can be more smoothly dissipated outside from the terminal portion 12A. Also, by arranging the coil 31 between the semiconductor chip 2 and the terminal portion 12C, loss on a path from the semiconductor chip 2 via the coil 31 can be reduced.

By providing the capacitor 32a having the largest capacitance close to the terminal portion 12A and the terminal portion 12B, a function such as noise removal can be exhibited appropriately without setting the capacitor 32a to an excessively large capacitance.

As a result of the substrate 4 including the principal surface wiring pattern 42, the reverse surface wiring pattern 43, and the plurality of through conductive portions 44, conduction paths in which portions of the wiring patterns overlap each other when viewed in the z direction can be configured. This is suitable for arranging the semiconductor chip 2 and the plurality of passive electronic components 3 more compactly when viewed in the z direction.

As a result of the base 41 being made of a ceramic, the heat from the semiconductor chip 2 and the plurality of coils 31 can be conducted to the island portion 11A more smoothly. Also, the base 41 has an advantage that the thermal expansion thereof is relatively small and there is little deformation during use.

As a result of the end side of the substrate 4 in the y direction coinciding with the lower end side of the island portion 11A in the y direction from which the terminal portion 12A protrudes, as shown in FIG. 9, the lengths of the wires 49 that connect the substrate 4 to the pad portion 13A, the pad portion 13B, and the pad portion 13C can be reduced. This contributes to reduction of the resistance.

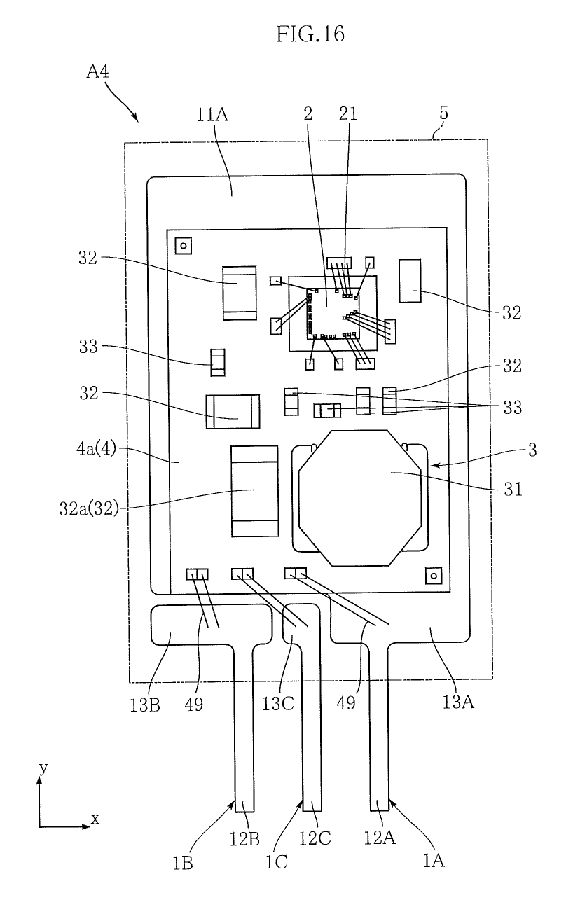

FIG. 16 shows a semiconductor device based on a fourth embodiment according to the present invention. In A4 of the present embodiment, a terminal portion 12A of a main lead 1A is arranged at the right end in the x direction in the diagram relative to a terminal portion 12B of a sub lead 1B and a terminal portion 12C of a sub lead 1C. Also, the terminal portion 12A is arranged closest, in the x direction, to a coil 31 that generates the largest amount of heat among a plurality of passive electronic components 3.

In the present embodiment, the terminal portion 12C functions as a ground terminal, the terminal portion 12B functions as an input terminal, and the terminal portion 12A functions as an output terminal. The remaining configuration of the semiconductor device A4 is in common with the aforementioned semiconductor device A3.

According to this embodiment as well, miniaturization and improved heat dissipation of the semiconductor device A4 can be realized. Also, the terminal portion 12A that is connected to an island portion 11A is arranged close to the coil 31 than are the terminal portion 12B and the terminal portion 12C. Accordingly, the heat from the coil 31 that generates the largest amount of heat can be more smoothly dissipated outside via the terminal portion 12A.

The semiconductor device according to the present invention is not limited to the abovementioned embodiments. Various design changes can be freely implemented with respect to the specific configuration of each part of the semiconductor device according to the present invention.

1. A semiconductor device comprising:
a semiconductor chip including a functional circuit;
a plurality of passive electronic components that assist a function of the semiconductor chip;
a substrate including a principal surface and a reverse surface that face in opposite directions to each other, the semiconductor chip and the plurality of passive electronic components being mounted on the principal surface;
a main lead including an island portion joined to the reverse surface of the substrate, and a terminal portion located on one side in a first direction relative to the island portion; and
a sealing resin that covers the semiconductor chip, the substrate, and the island portion of the main lead.

2. The semiconductor device according to claim 1, wherein the semiconductor chip and the plurality of electronic components are mounted on the substrate.

3. The semiconductor device according to claim 2, wherein the plurality of passive electronic components include a coil.

4. The semiconductor device according to claim 3, wherein the coil generates a largest amount of heat among the plurality of passive electronic components.

5. The semiconductor device according to claim 4, wherein the coil is located between the semiconductor chip and the terminal portion in the first direction.

6. The semiconductor device according to claim 2, wherein the plurality of passive electronic components include a capacitor.

7. The semiconductor device according to claim 6, wherein the capacitor is located between the semiconductor chip and the terminal portion in the first direction.

8. The semiconductor device according to claim 2, wherein the plurality of passive electronic components include a plurality of capacitors, and a capacitor having a largest capacitance among the plurality of capacitors is arranged closest to the terminal portion in the first direction.

9. The semiconductor device according to claim 2, wherein the substrate includes: a base made of an insulating material and providing the principal surface and the reverse surface; and a principal surface wiring pattern formed on the principal surface of the base.

10. The semiconductor device according to claim 9, wherein the substrate includes a reverse surface wiring pattern formed on the reverse surface of the base.

11. The semiconductor device according to claim 10, wherein the substrate includes a through conductive portion that passes through the base and electrically connects the principal surface pattern and the reverse surface wiring pattern.

12. The semiconductor device according to claim 11, further comprising a resist layer that covers the reverse surface wiring pattern.

13. The semiconductor device according to claim 9, wherein the base is made of a ceramic.

14. The semiconductor device according to claim 2, wherein the island portion is larger than the substrate in plan view.

15. The semiconductor device according to claim 14, wherein the island portion and the substrate are rectangular in plan view.

16. The semiconductor device according to claim 15, wherein the substrate is arranged close to the terminal portion in the first direction relative to the island portion.

17. The semiconductor device according to claim 16, wherein the island portion includes a side to which the terminal portion is connected, and said side of the island portion coincides with a side of the substrate coincide in plan view.

18. The semiconductor device according to claim 2, comprising a plurality of sub leads that respectively include terminal portions arrayed with the terminal portion of the main lead in a second direction that intersects the first direction.

19. The semiconductor device according to claim 18, wherein the terminal portion of the main lead is provided between the terminal portions of two of the sub leads.

20. The semiconductor device according to claim 19, wherein the terminal portion of the main lead is a ground terminal, and terminal portions of the plurality of sub leads include an input terminal and an output terminal.

21. The semiconductor device according to claim 18, wherein the terminal portion of the main lead is arranged at a furthest end in the second direction relative to the plurality of sub leads.

22. The semiconductor device according to claim 21, wherein the terminal portion of the main lead is provided closer, in the second direction, to the component that generates a largest amount of heat among the plurality of passive electronic components than are the plurality of sub leads.

23. The semiconductor device according to claim 21, wherein the terminal portion of the main lead is an output terminal, and terminal portions of the plurality of sub leads includes an input terminal and a ground terminal.

24. The semiconductor device according to claim 1, functioning as a DC/DC converter.
